(19) United States
(12) Patent Application Publication
(10) Pub. No.: US 2026/0282734 A1
(43) Pub. Date: Sep. 17, 2026

(54) COMPOUND, AND PREPARATION METHOD AND USE THEREOF

(71) Applicant: AGLAIA TECH (HONG KONG) INNOVATION CENTER LIMITED, Hong Kong (CN)

(72) Inventors: Chi Ming CHE, Hong Kong (CN); Huiyang LI, Hong Kong (CN)

(73) Assignee: AGLAIA TECH (HONG KONG) INNOVATION CENTER LIMITED, Hong Kong (CN)

(21) Appl. No.: 19/166,160

(22) PCT Filed: Apr. 28, 2023
(86) PCT No.: PCT/CN2023/091692

§ 371 Date: Sep. 17, 2025

(30) Foreign Application Priority Data
Mar. 20, 2023 (CN) 202310272402.6

(51) Int. Cl. H10K 85/30; C07F 1/00; C09K 11/02; C09K 11/06; H10K 50/11; H10K 101/25

(52) U.S. Cl. CPC H10K 85/371; C07F 1/00; C09K 11/02; C09K 11/06; C09K 2211/1007; C09K 2211/1029; C09K 2211/188; H10K 50/11; H10K 2101/25

(57) ABSTRACT

A compound, and a preparation method and use thereof are disclosed. The compound can be combined with a selective host material to form a TADF exciplex luminophore, which has a high luminescence quantum yield, radiation attenuation rate, and a short luminescence service life (no more than 5 microseconds). The TADF exciplex luminophore is applied to an organic electroluminescent device. The device presents better device performance, and its maximum current efficiency and external quantum efficiency reach 36% and 12% respectively.

### CROSS-REFERENCE TO RELATED APPLICATION

This application claims priority of Chinese Patent Application No. 202310272402.6 entitled “COMPOUND, AND PREPARATION METHOD AND USE THEREOF” and filed with the China National Intellectual Property Administration on Mar. 20, 2023, the entire disclosures of which are incorporated herein by reference.

### TECHNICAL FIELD

The present disclosure relates to the field of an organic photoelectric device, and in particular, to a compound, and a preparation method and use thereof.

### BACKGROUND

An organic electroluminescent light-emitting diode (OLED) is a display and lighting device that has been popularized in recent years, and is mainly used in a display screen of an electronic product, such as a mobile phone, a TV set, or a notebook computer. Because a light-emitting material in the OLED has significant influence on device performance, it is of important significance to develop a light-emitting material that has high performance, is inexpensive, and is convenient for extensive production.

The light-emitting material can be roughly classified into a phosphorescent material and a fluorescent material. Generally, when molecules of an ordinary fluorescent material are excited, electrons transition from a ground state (S0) to a singlet excited state (S1), and then return to the ground state via a radiation attenuation process, thus emitting fluorescence. However, an OLED using an ordinary fluorescent material has a theoretical internal quantum efficiency (IQE) of only about 25% because triplet excitons are not utilized. However, in a phosphorescent metal complex, heavy metal atom effect increases intersystem crossing (ISC) rate, allowing molecules to cross from the singlet excited state (S1) to the triplet excited state (T1) through an intersystem crossing process, and then return from the T1 state to the ground state (S0) through radiation, thus emitting phosphorescence. The phosphorescent metal complex is used as a light-emitting material for the OLED to effectively utilize singlet and triplet excitons, which can achieve 100% IQE. However, because radiative transition from the T1 state to the ground state S0 is spin-forbidden, the phosphorescent metal complex has a relatively low radiation attenuation rate, thereby resulting in a long luminescence service life. The longer the luminescence service life is, the more the reverse intersystem crossing (RISC) and self-quenching consumptions are, the lower the corresponding quantum efficiency is.

A phosphorescent gold (III) complex in the existing technology generally has a luminescence service life of up to tens of microseconds, and a relatively slow radiation attenuation rate constant (kr) in a range of 10³ s⁻¹. When used in an OLED device, these light-emitting materials will present severe external quantum efficiency roll-off at a high current density, thus impacting practical applications thereof. Therefore, the OLED device tends to require the light-emitting materials to have high quantum efficiency, short luminescence service life, and high radiation attenuation rate.

At present, a thermally activated delayed fluorescence (TADF) material, as a new generation of light-emitting material, has a sufficiently small energy difference between S1 and T1 states (ΔEST). In OLED applications, the TADF material can be thermally activated by surrounding heat, effectively utilize triplet excitons through a reverse intersystem crossing (RISC) process, and promote conversion of the triplet excitons into singlet excitons, thus emitting delayed fluorescence. Therefore, the OLED using the TADF material can effectively utilize singlet and triplet excitons, and can also achieve 100% IQE.

### SUMMARY

In view of the above, an object of the present disclosure is to provide a compound, and a preparation method and use thereof. The compound can be combined with a selective host material to form a TADF exciplex luminophore, which has a high luminescence quantum yield, high radiation attenuation rate, and a short luminescence service life.

In order to achieve this object, the present disclosure employs the following technical schemes.

In the first aspect, the present disclosure provides a compound having a structure of formula I:

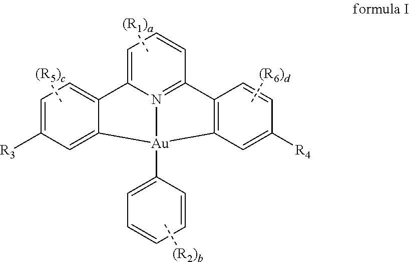

wherein R₁ and R₂ are independently selected from H, halogen, a substituted or unsubstituted C₁-C₆ alkyl, a substituted or unsubstituted C₁-C₆ alkoxy, —O—R₇, a substituted or unsubstituted C₆-C₃₀ aryl, or a substituted or unsubstituted C₄-C₂₀ heteroaryl;
R₇ is independently selected from a substituted or unsubstituted C₁-C₆ alkyl, a substituted or unsubstituted C₆-C₂₀ aryl, or a substituted or unsubstituted C₄-C₂₀ heteroaryl;
a and b are independently selected from any integer of 0 to 3;
or, two R₂ form, together with C to which they are attached, a substituted or unsubstituted ring or heterocycle;
heteroatoms in the heteroaryl or the heterocycle are independently selected from any one or more of N, O, P, or S;
R₃, R₄, R₅, and R₆ are independently selected from H, halogen, nitro, a substituted or unsubstituted C₁-C₆ alkyl, cyano, sulfonyl, acyl, or carboxyl; and
c and d are independently selected from any integer of 0 to 3.

Preferably, R₁ and R₂ are independently selected from H, halogen, —O—R₇, a substituted or unsubstituted C₁-C₄ alkyl, a substituted or unsubstituted C₁-C₄ alkoxy, or a substituted or unsubstituted C₆-C₂₀ aryl.

Alternatively, two R₂ form, together with the C to which they are attached, a substituted or unsubstituted five-membered ring or five-membered heterocycle; and heteroatoms in the five-membered heterocycle are independently selected from any one or more of N, O, P, or S.

Preferably, R₃, R₄, R₅, and R₆ are independently selected from H, halogen, nitro, or a substituted or unsubstituted C₁-C₄ alkyl.

More preferably, R₃, R₄, R₅, and R₆ are independently selected from H, F, nitro, or trifluoromethyl.

Further preferably, structural formula of the compound is selected from any one of formula 1 to formula 20 below:

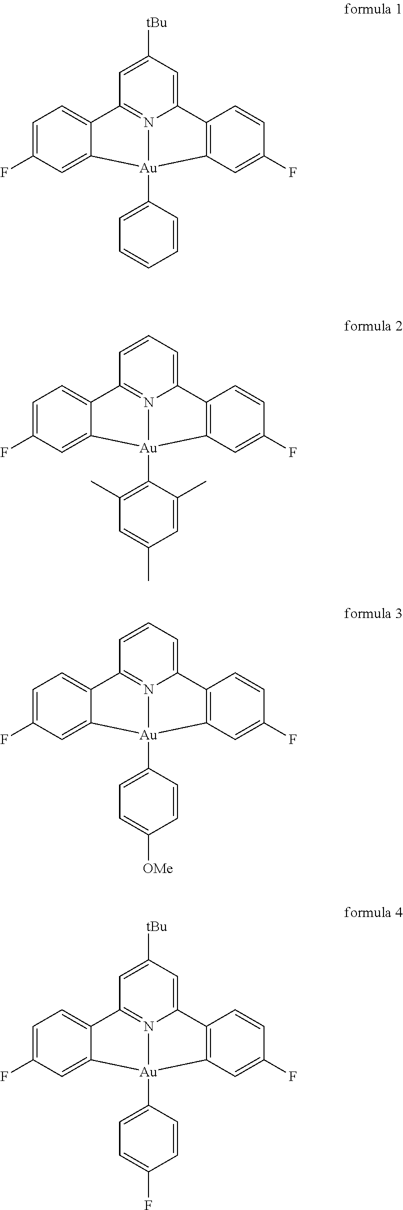

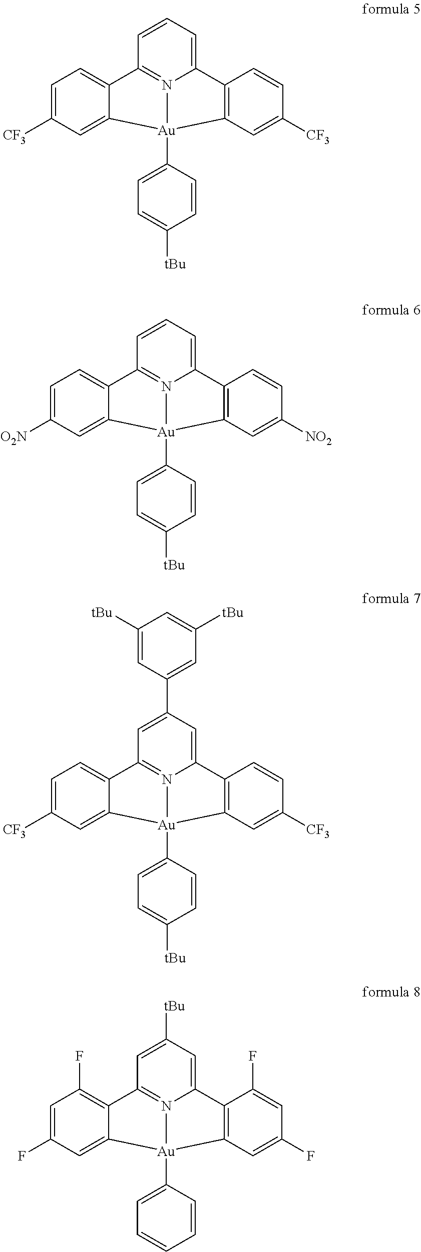

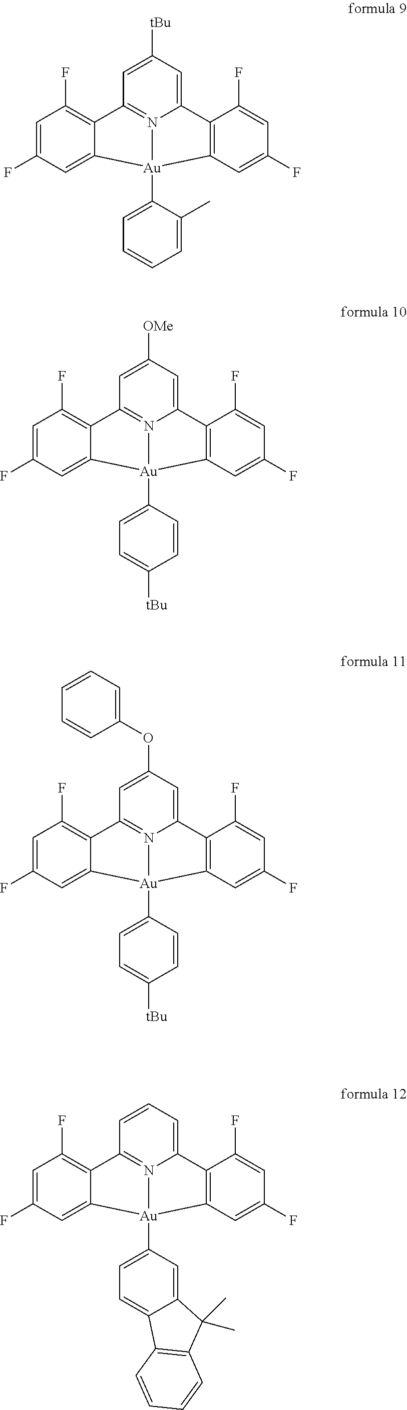

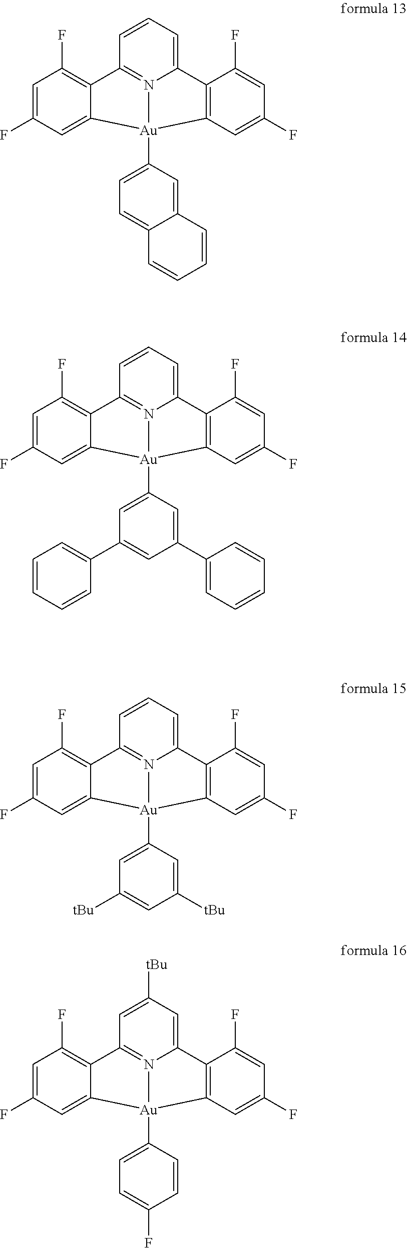

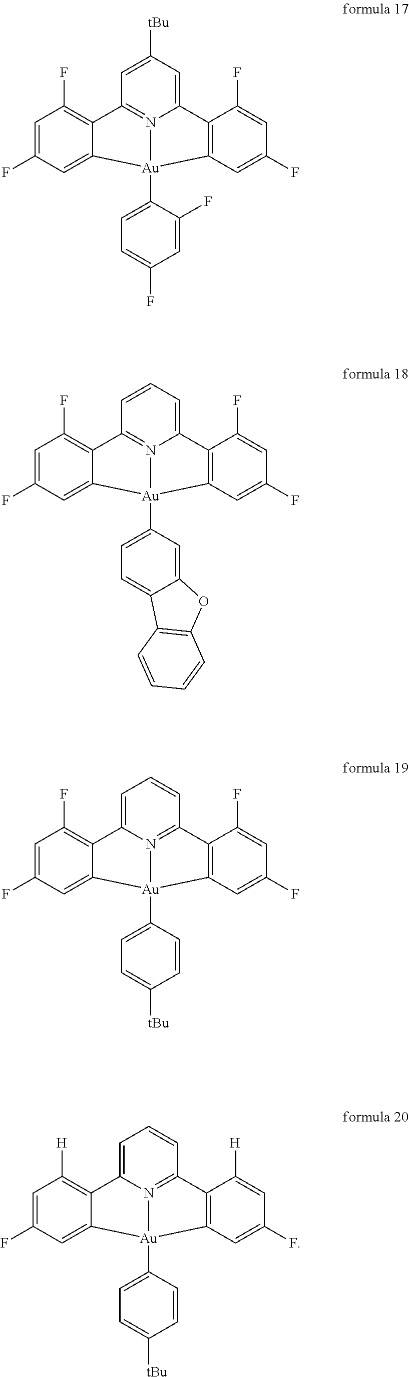

In the second aspect, the present disclosure provides a method for preparing the above compound, including the following steps:
mixing a raw material as shown in formula A, a raw material as shown in formula B, a solvent, a catalyst, and an alkaline substance, and then heating the mixture for reaction to obtain the compound;

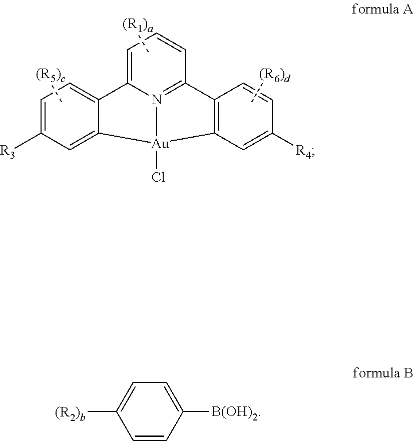

Preferably, the solvent includes toluene.

Preferably, the catalyst includes bis(di-tert-butyl (4-dimethylaminophenyl)phosphine)dichloropalladium.

Preferably, the alkaline substance includes potassium carbonate.

In the third aspect, the present disclosure provides a TADF exciplex luminophore, including a dopant and a host material. The dopant is the compound involved in the above technical schemes.

Preferably, a structural formula of the host material is selected from any one of formula (B-1) to formula (B-8) below:

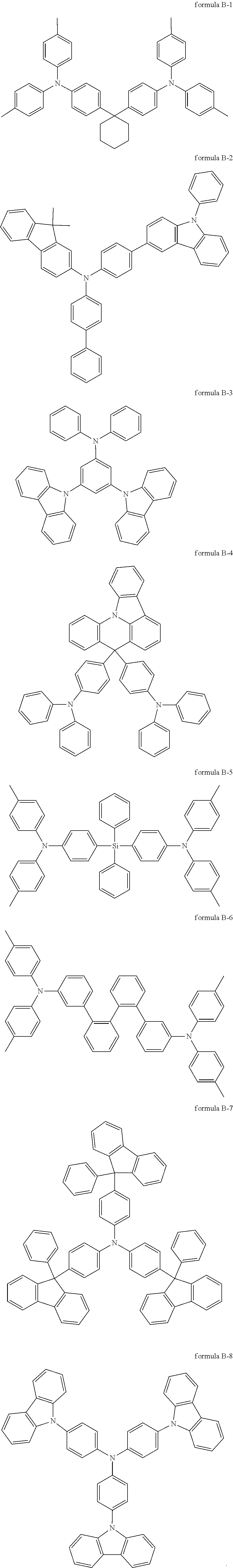

Preferably, the host material is selected from any one or more of the above formula (B-1) to formula (B-8).

Preferably, the TADF exciplex luminophore has a luminescence quantum yield of at least 30% and a luminescence service life of no more than 5 microseconds.

In the fourth aspect, the present disclosure provides use of the above TADF exciplex luminophore in the manufacture of an organic electroluminescent device, a light-emitting electrochemical cell, or a chemical sensor.

In the fifth aspect, the present disclosure provides an organic electroluminescent device including an anode, a cathode, and an interlayer arranged between the anode and the cathode, where:

the interlayer includes a light-emitting layer, the light-emitting layer including the TADF exciplex luminophore involved in the above technical schemes.

Compared with the existing technology, the present disclosure has the following beneficial effects.
(1) The present disclosure provides a compound (i.e., a phosphorescent gold (III) complex), which is readily implementable with a simple preparation method, is inexpensive, and is conductive to industrial production; the compound can be combined with a selective host material to form a TADF exciplex luminophore, which has a high luminescence quantum yield, radiation attenuation rate, and a short luminescence service life (no more than 5 microseconds);
(2) The present disclosure provides a new light-emitting channel for the phosphorescent gold (III) complex, broadens material applications thereof, and shows a new strategy for implementing a gold (III)-TADF light-emitting system. Since the gold (III) complex in such a TADF exciplex can implement TADF without the need for configuration of an N-donor, the synthesis of the gold (III) complex is less restricted, thus facilitating massive synthesis, so that the donor/acceptor combination between the gold (III) complex and the host material molecules is more flexible;
(3) The TADF exciplex luminophore is applied to an organic electroluminescent device. The device thus prepared presents better device performance, and its maximum current efficiency and external quantum efficiency reach 36% and 12% respectively.

### BRIEF DESCRIPTION OF DRAWINGS

FIG. 1 shows luminescence spectra of gold (III) complexes Au1, Au2, and Au3 measured in degassed toluene (298 K);

FIG. 2 shows luminescence spectra of gold (III) complexes Au1, Au2, and Au3 measured in a TAPC film (298 K);

FIG. 3 shows luminescence spectra of gold (III) complexes Au1, Au2, and Au3 measured in an mCP film (298 K);

FIG. 4 shows a cyclic voltammogram of a gold (III) complex Au2;

FIG. 5 shows a cyclic voltammogram of a gold (III) complex Au3;

FIG. 6 shows a spectrum chart of an organic electroluminescent device using an Au2-TAPC exciplex as a light-emitting layer; wherein panel a of FIG. 6 is a normalized electroluminescence spectrum at different wavelengths, panel b of FIG. 6 is an external quantum efficiency curve at different luminances; panel c of FIG. 6 is a luminance curve at different voltages, and panel d of FIG. 6 is a current density curve at different voltages; and

FIG. 7 is a spectrum chart of an organic electroluminescent device using an Au3-TAPC exciplex as a light-emitting layer; wherein panel a of FIG. 7 is a normalized electroluminescence spectrum at different wavelengths, panel b of FIG. 7 is an external quantum efficiency curve at different luminances; panel c of FIG. 7 is a luminance curve at different voltages, and panel d of FIG. 7 is a current density curve at different voltages.

### DETAILED DESCRIPTION

Technical schemes in the present disclosure will be clearly and completely described below with reference to the embodiments of the present disclosure. Apparently, the embodiments described below are merely a part, instead of all, of the embodiments of the present disclosure. All other embodiments obtained by those of ordinary skills in the art based on the embodiments of the present disclosure without making creative work are encompassed within the scope of protection of the present disclosure.

In view of the problems of low quantum efficiency, long luminescence service life, and low radiation attenuation rate of the light-emitting material in the organic electroluminescent device of the existing technology, the present disclosure provides a compound having a structure of formula I:

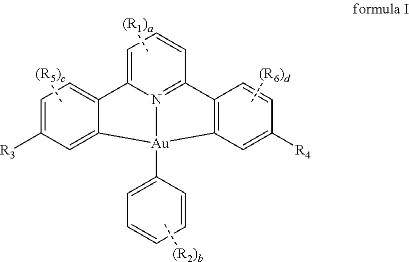

wherein R₁ and R₂ are independently selected from H, halogen, a substituted or unsubstituted C₁-C₆ alkyl, a substituted or unsubstituted C₁-C₆ alkoxy, —O—R₇, a substituted or unsubstituted C₆-C₃₀ aryl, or a substituted or unsubstituted C₄-C₂₀ heteroaryl;
R₇ is independently selected from a substituted or unsubstituted C₁-C₆ alkyl, a substituted or unsubstituted C₆-C₂₀ aryl, or a substituted or unsubstituted C₄-C₂₀ heteroaryl;
a and b are independently selected from any integer of 0 to 3;
or, two R₂ form, together with C to which they are attached, a substituted or unsubstituted ring or heterocycle;
heteroatoms in the heteroaryl or the heterocycle are independently selected from any one or more of N, O, P, or S;
R₃, R₄, R₅, and R₆ are independently selected from H, halogen, nitro, a substituted or unsubstituted C₁-C₆ alkyl, cyano, sulfonyl, acyl, or carboxyl; and
c and d are independently selected from any integer of 0 to 3.

The above “substitution” means that a hydrogen atom bonded to a carbon atom of the compound becomes another substituent, and the substitution site is not limited as long as the site is a site where the hydrogen atom is substituted, that is, a site where the hydrogen atom can be substituted with the substituent, and when two or more hydrogen atoms are substituted with two or more substituents, the two or more substituents may be identical to or different from each other.

The term “substituted or unsubstituted” means to be substituted with deuterium, halogen group, cyano, hydroxyl, carbonyl, ester group, silyl, boryl, alkyl, cycloalkyl, alkoxy, alkenyl, alkylamino, heterocyclylamino, arylamino, aryl, or heterocyclyl, or a substituent attached to two or more of the substituents shown above, or to have no substituent.

In some embodiments of the present disclosure, the compound has a structure of formula I, wherein R₁ and R₂ are independently preferably selected from H, halogen, —O—R₇, a substituted or unsubstituted C₁-C₄ alkyl, a substituted or unsubstituted C₁-C₄ alkoxy, a substituted or unsubstituted C₆-C₂₀ aryl; or two R₂ form, together with the C to which they are attached, a substituted or unsubstituted five-membered ring or five-membered heterocycle; and heteroatoms in the five-membered heterocycle are independently selected from any one or more of N, O, P, or S. R₃, R₄, R₅, and R₆ are independently selected from H, halogen, nitro, or a substituted or unsubstituted C₁-C₄ alkyl.

In some embodiments of the present disclosure, structural formula of the compound is specifically selected from any one of formula 1 to formula 20:

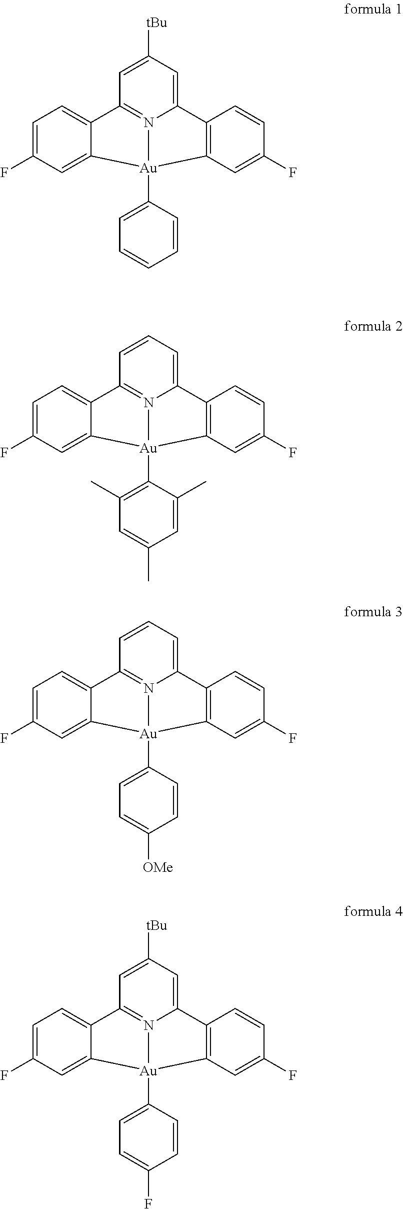

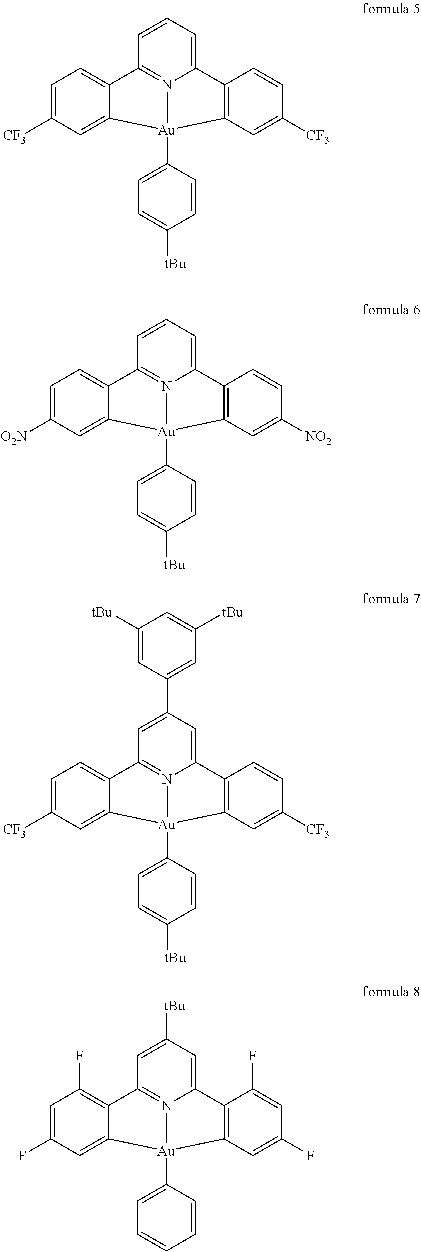

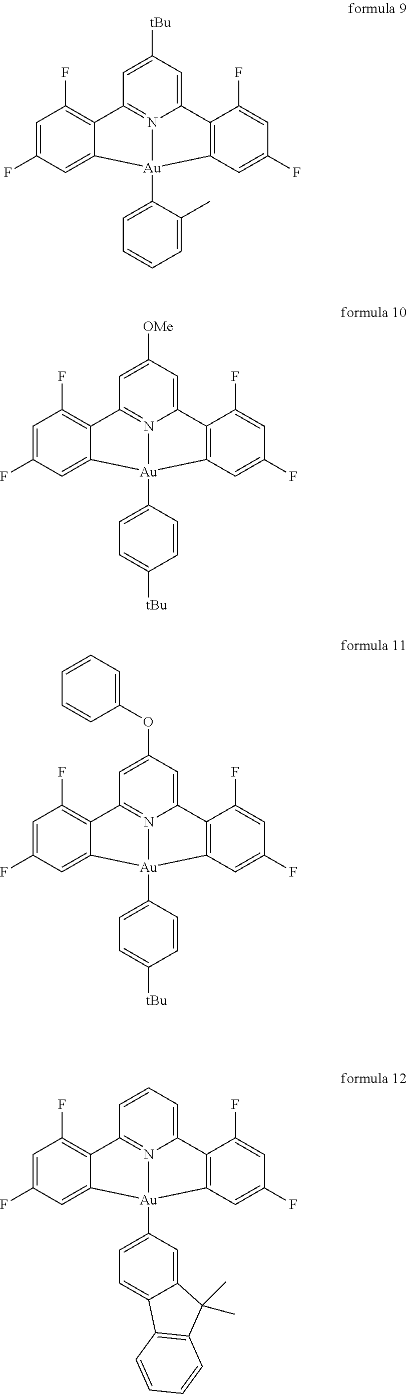

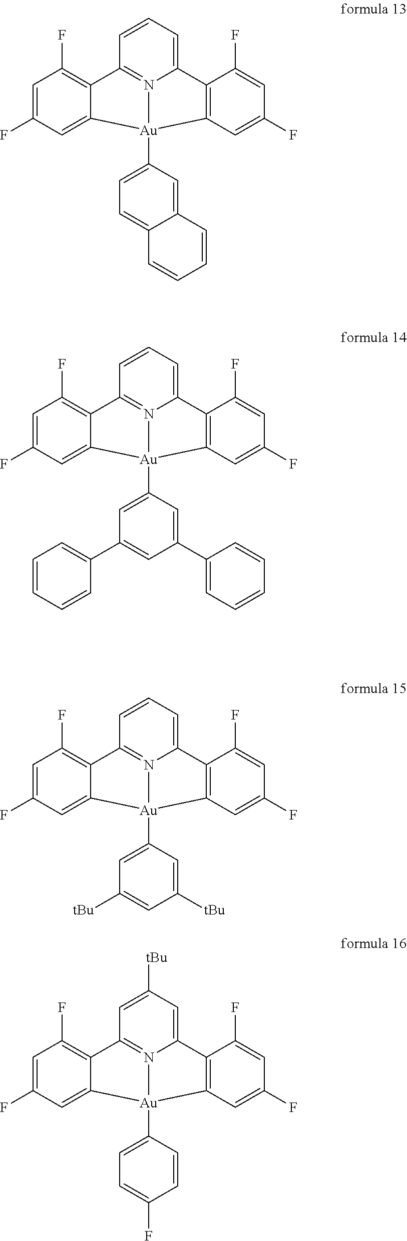

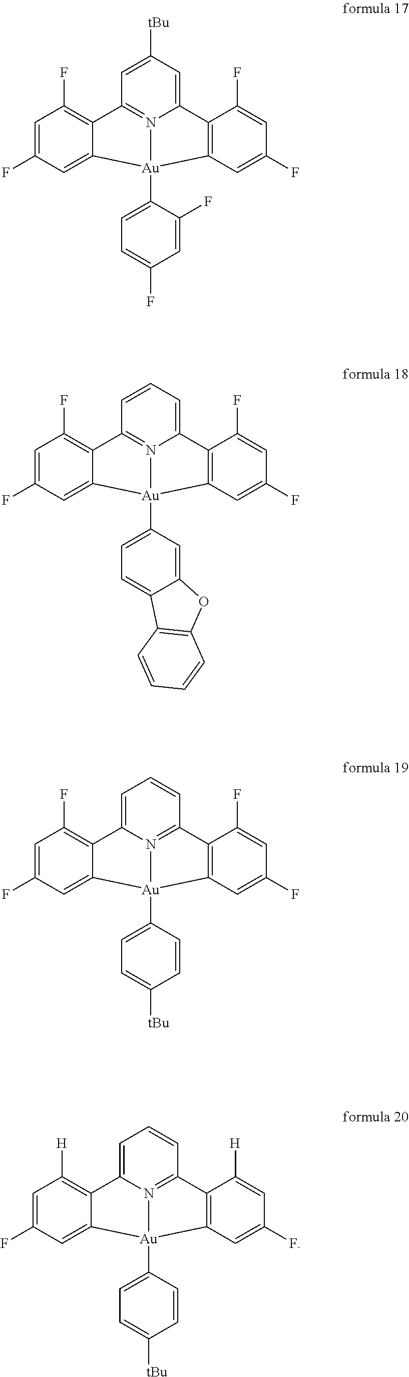

The compound provided in the present disclosure belongs to a phosphorescent gold (III) complex, and is found through studies to be capable of forming a thermally activated delayed fluorescence (TADF) exciplex luminophore with a selective host material (strong electron donor), with an intermolecular charge transfer process occurring between the host material (electron donor) and the gold (III) complex (electron acceptor). The TADF exciplex luminophore presents different spectral curves and low energy green electroluminescent TADF. The luminescent quantum yield can be increased to up to 0.65, and the luminescence service life is greatly shortened to less than 5 microseconds. The radiation attenuation constant is enhanced, reaching a maximum of 2×10⁵ s⁻¹, which is much higher than the value (10³ s⁻¹) observed in the corresponding phosphorescent gold (III) complex. The TADF exciplex luminophore can serve as a light-emitting layer in an organic electroluminescent device, so that the device retains TADF properties, and has excellent performance, and its maximum current efficiency and external quantum efficiency reach 36% and 12% respectively.

The present disclosure further provides a method for preparing the compound, including the following steps:
mixing a raw material as shown in formula A, a raw material as shown in formula B, a solvent, a catalyst, and an alkaline substance, and then heating the mixture for reaction to obtain the compound;

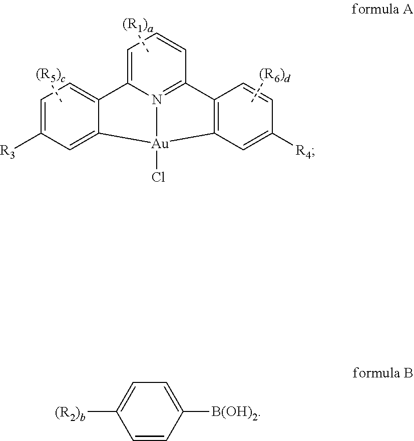

In some embodiments of the present disclosure, a raw material as shown in formula A, a raw material as shown in formula B, a solvent, a catalyst, and an alkaline substance are mixed, and then the mixture is heated for reaction to obtain the compound. The solvent may be selected from toluene; the catalyst is selected from bis(di-tert-butyl (4-dimethylaminophenyl)phosphine)dichloropalladium; and the alkaline substance is selected from potassium carbonate. In some embodiments of the present disclosure, the raw material as shown in formula 1, the raw material as shown in formula 2, the catalyst, and the alkaline substance are preferably dissolved in a solvent at a molar ratio of 1:(1.1-1.4):(0.04-0.1):(0.003-0.03), with a ratio of the raw material as shown in formula 1 to the solvent being 1 mol:(10-20) mL. Then, the reaction system is heated to a temperature of 90° C. to 120° C. for reaction for 10 h to 20 h. In some embodiments of the present disclosure, after the reaction is complete, the reaction system is preferably evaporated under reduced pressure to remove the solvent, thus providing a crude substance. Then, the crude substance is purified to provide a compound satisfying the purity requirements. In some embodiments of the present disclosure, the crude substance is preferably subjected to silica gel column chromatography with dichloromethane as the solvent and with n-hexane and dichloromethane as the eluents. The volume ratio of n-hexane to dichloromethane is (9:1).

The method for preparing the above compound provided in the present disclosure is simple, is readily implementable at low costs without the need to use expensive instruments and devices, and is conducive to industrial production.

The present disclosure further provides a thermally activated delayed fluorescence (TADF) exciplex luminophore formed from the compound involved in the above technical schemes and a selective host material. In some embodiments of the present disclosure, a mass ratio of the host material to the dopant is (80-95):(5-20), wherein structural formula of the selective host material is specifically selected from any one of formula (B-1) to formula (B-8) below:

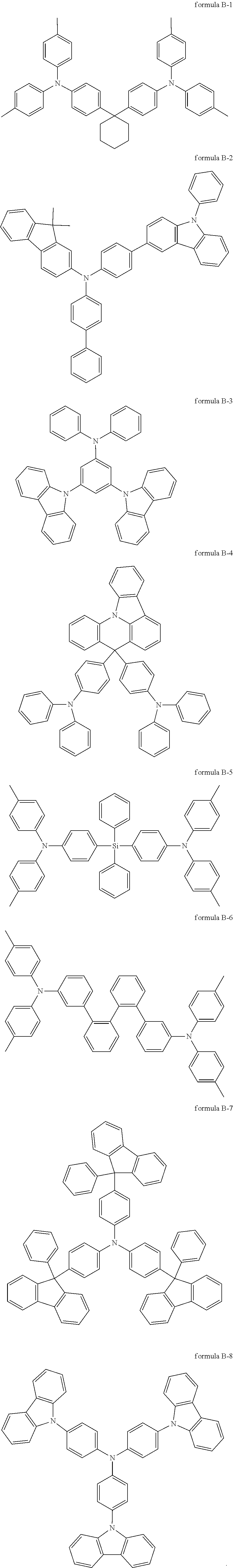

The compound provided in the present disclosure can be combined with any one or more of the above selective host materials to form a TADF exciplex luminophore, which has a luminescence quantum yield of at least 30% and a luminescence service life of no more than 5 microseconds.

The above TADF exciplex luminophore can be used for the manufacture of an organic electroluminescent device, a light-emitting electrochemical cell, or a chemical sensor.

In view of the above, the present disclosure further provides an organic electroluminescent device, including an anode, a cathode, and an interlayer arranged between the anode and the cathode. In the present disclosure, the anode is selected from indium tin oxide, tin oxide, zinc oxide, or indium oxide, and has a thickness of 180 nm; while the cathode is selected from Al, Li, Mg, Ca, Au, Ag, or Pb, and has a thickness of 100 nm to 120 nm. The interlayer includes a light-emitting layer, the light-emitting layer including the TADF exciplex luminophore involved in the above technical schemes.

In some embodiments of the present disclosure, the interlayer further includes a functional layer, the functional layer including any one or more of a hole injection layer, a hole transport layer, a hole injection-hole transport functional layer, an electron blocking layer, a hole blocking layer, an electron transport layer, an electron injection layer, or an electron transport-electron injection functional layer.

The present disclosure does not impose any limitation on the method for preparing an organic electroluminescent device, and preferably produces the organic electroluminescent device by evaporating a metal, a conductive oxide, or an alloy thereof onto a substrate using, e.g., thin film evaporation, electron beam evaporation, or physical vapor deposition, to form the anode, then forming the interlayer thereon, and evaporating the cathode.

The compound provided in the present disclosure can be combined with the selective host material as shown in the above formula (B-1) to formula (B-8) to form a TADF exciplex luminophore, which has a high luminescence quantum yield, radiation attenuation rate, and a short luminescence service life (no more than 5 microseconds). The organic electroluminescent device using the TADF exciplex luminophore in the light-emitting layer can present better device performance, and its maximum current efficiency and external quantum efficiency reach 36% and 12% respectively.

To further illustrate the present disclosure, detailed description is provided below with reference to the following examples. The sources of the raw materials used in the following examples of the present disclosure are not particularly limited, and can all be purchased from the market or prepared according to conventional preparation methods well known to those having ordinary skills in the art.

### Comparative Example 1

This comparative example provides a phosphorescent gold (III) complex Au1 with the synthesis route as follows:

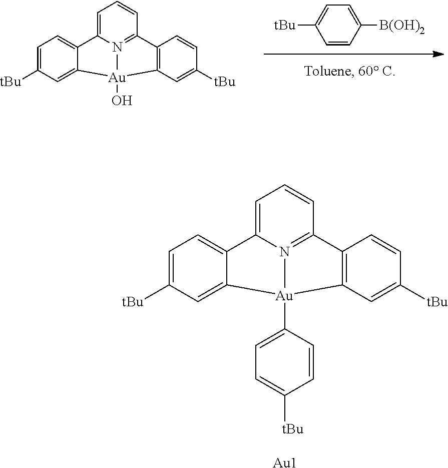

The specific preparation method is as follows:
(1) (tBu-Ph₂Py) AuOH (40 mg, 0.072 mmol) and (tBu-C₆H₄)B(OH)₂ (13 mg, 0.072 mmol) were mixed in toluene (20 mL) to obtain a mixture, and the mixture was heated to a reaction temperature of 60° C. for reaction for 12 h;
(2) the reaction mixture was evaporated under reduced pressure to remove a solvent, thus obtaining a solid;
(3) the solid was rinsed with petroleum ether (2 times, 3 mL each time), then dissolved in CH₂Cl₂, and filtered through a silica gel plug; and
(4) the filtrate obtained in the step (3) was evaporated under reduced pressure to obtain a target product Au1.

The yield was calculated and the hydrogen spectrum was tested for the target product Au1, with the results as follows:
Yield: 24 mg (50%, light yellow solid);
¹H NMR (500 MHz, CDCl₃) δ/ppm=7.79 (t, J=7.8 Hz, 1H), 7.61 (d, J=7.3 Hz, 2H), 7.57-7.55 (m, 4H), 7.46 (d, J=7.9 Hz, 2H), 7.34 (d, J=7.6 Hz, 2H), 7.25 (d, J=8.0 Hz, 2H), 1.39 (s, 9H), 1.26 (s, 18H); HR-MS (ESI): m/z calcd, for [C₃₅H₄₁AuN]+ [M+H]+: 672.2899, found: 672.2897.

### Example 1

This example provides a phosphorescent gold (III) complex Au2 with the synthesis route as follows:

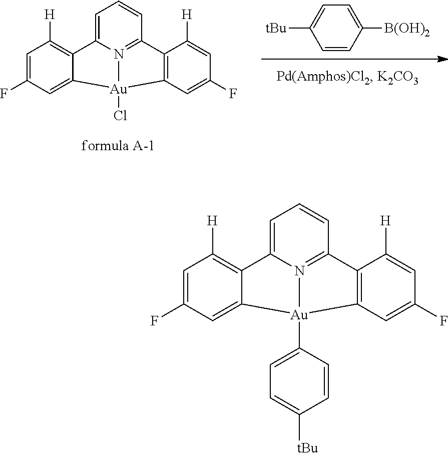

The specific preparation method is as follows:
(1) the raw material as shown in formula A-1 (100 mg, 1 eq), (tBu-C₆H₄)B(OH)₂ (1.1 molar eq), K₂CO₃ (2 m, 2 mL), and Pd(AmPhos)Cl₂ (0.05 eq) were mixed in toluene (15 mL) to obtain a mixture, and the mixture was heated to a reaction temperature of 110° C. for reaction for 12 h;
(2) the reaction mixture obtained in the step (1) was evaporated under reduced pressure to remove a solvent, thus obtaining a crude substance; and
(3) the crude substance was purified through a silica gel chromatographic column under a condition for the silica gel chromatographic column that: the crude substance mixed with dichloromethane (as the solvent) was injected into the silica gel column with n-hexane and dichloromethane (9:1, volume ratio) selected as the eluents.

The yield was calculated and the hydrogen spectrum was tested for the target product Au2, with the results as follows:

Yield: 120 mg (50%, yellow solid);

1H NMR (500 MHz, CDCl₃) δ/ppm=7.82 (t, J=8.0 Hz, 1H), 7.62 (dd, J=8.3, 4.8 Hz, 2H), 7.49 (d, J=7.8 Hz, 2H), 7.43 (d, J=7.9 Hz, 2H), 7.34 (d, J=7.6 Hz, 2H), 7.14 (d, J=7.9 Hz, 2H), 6.86 (t, J=8.5 Hz, 2H), 1.40 (s, 9H); ¹⁹F NMR (470 MHz, CDCl₃) δ/ppm=−107.5; HR-MS (ESI): m/z calcd, for [C₂₇H₂₃AuF₂N]⁺ [M+H]⁺: 596.1459, found: 596.1463.

### Example 2

This example provides a phosphorescent gold (III) complex Au3 with the synthesis route as follows:

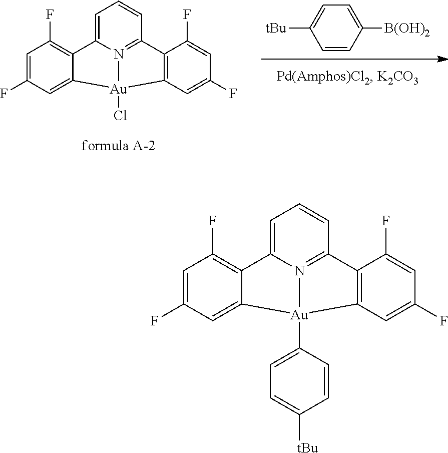

Example 2 is referred to for the synthesis method.

The yield was calculated and the hydrogen spectrum was tested for the target product Au3, with the results as follows:

Yield: 88 mg (74%, light yellow solid);

1H NMR (500 MHz, CD₂Cl₂) δ/ppm=7.87 (s, 3H), 7.42 (d, J=8.1 Hz, 2H), 7.32 (d, J=8.1 Hz, 2H), 6.90 (dd, J=7.0, 2.1 Hz, 2H), 6.62 (ddd, J=11.8, 9.0, 2.3 Hz, 2H), 1.39 (s, 9H). ¹⁹F NMR (470 MHz, CDCl₃) δ/ppm=−104.5, −108.6; HR-MS (ESI): m/z calcd. for [C₂₇H₂₁AuF₄N]⁺ [M+H]⁺: 632.1270, found: 632.1260.

The Au1, the Au2, and the Au3 obtained in Comparative Example 1 and Examples 1-2 were photophysically characterized in thin films and degassed toluene (298 K), wherein the luminescence service life was measured in the instrument “Quanta Ray GCR 150-10 pulsed Nd:YAG laser system” (laser wavelength: 355 nm). At a constant luminescence wavelength, the attenuation of the light intensity with time was observed. The calculation formula is as follows:

$$I ( t ) = {I}_{0} {e}^{- t / τ} ;$$

I₀ is an initial light intensity, I(t) is a light intensity at time t, and τ is a luminescence service life.

The luminescence quantum yield was measured using the instrument “Hamamatsu C11347 Quantaurus-QY Absolute PL quantum yields measurement system”.

The calculation formula of the radiation attenuation rate constant (kᵣ): kᵣ=Φ/τ (Φ is the luminescence quantum yield, and τ is the luminescence service life).

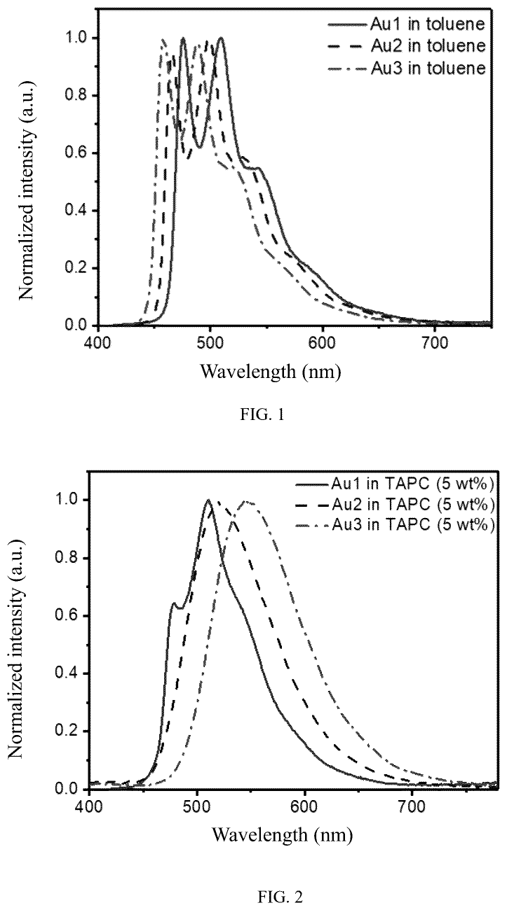

The results are shown in Table 1 and FIG. 1 to FIG. 3:

TABLE 1

| | | | | Radiation |
|---|---|---|---|---|
| Phosphorescent | | Luminescence | | attenuation rate |
| gold (III) | Test medium | wavelength | Luminescence | Constant (10³ |
| complex | (298K) | nm (τ/μs) | quantum yield | s⁻¹) |
| Au1 | Toluene (degassed) | 476, 510, 543 (45.8) | 0.09 | 2.0 |
| | 5 wt % in mCP film | 477, 511, 545 (110*) | 0.37 | 3.4 |
| | 5 wt % in TAPC film | 478, 511 (20.3*) | 0.17 | 8.4 |
| Au2 | Toluene (degassed) | 466, 499, 530 (68.7) | 0.12 | 1.8 |
| | 5 wt % in mCP film | 470, 502, 538 (75.7*) | 0.21 | 2.8 |
| | 5 wt % in TAPC film | 520 (4.8*) | 0.43 | 90 |
| Au3 | Toluene (degassed) | 459, 488, 521 (59.2) | 0.13 | 2.2 |
| | 5 wt % in mCP film | 465, 493, 533 (47.2) | 0.22 | 4.7 |
| | 5 wt % in TAPC film | 544 (3.3*) | 0.65 | 197 |

*Weighted mean luminescence service life

As can be seen from the data in Table 1, the Au1, the Au2, and the Au3 will present low radiation attenuation rates in the mCP film and degassed toluene (kᵣ is only 10³ s⁻¹), with an order of magnitude comparable to that of an ordinary phosphorescent gold (III) complex. However, the Au2 and the Au3 in the TAPC film can present a short luminescence service life (less than 5 microseconds), as well as a high luminescence quantum yield and radiation attenuation rate (kᵣ in a range of 0.90-1.97×10⁵ s⁻¹), which is thirty times more than that of the kᵣ measured in the mCP film (2.8-4.7×10³ s⁻¹).

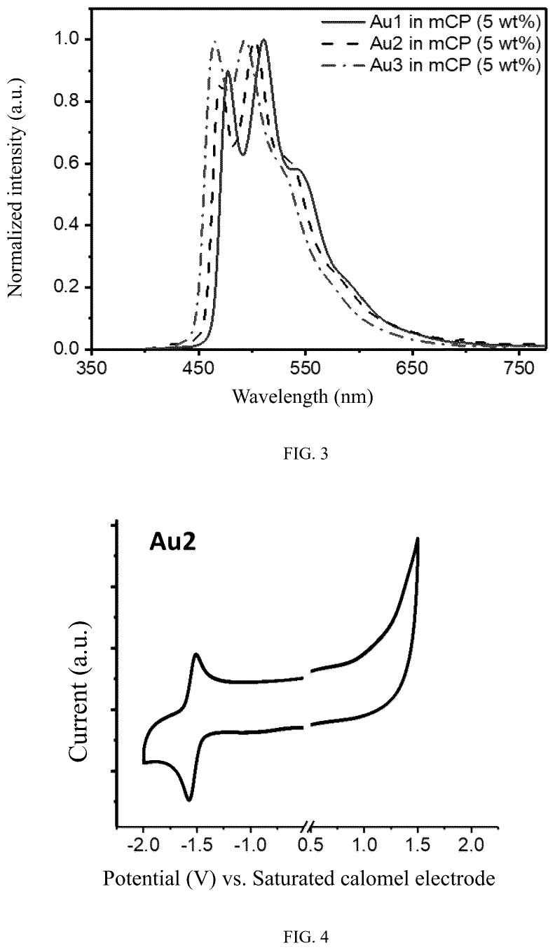

FIG. 1 shows luminescence spectra of phosphorescent gold (III) complexes Au1, Au2, and Au3 measured in degassed toluene (298 K); FIG. 2 shows luminescence spectra of phosphorescent gold (III) complexes Au1, Au2, and Au3 measured in a TAPC film (298 K); and FIG. 3 shows luminescence spectra of phosphorescent gold (III) complexes Au1, Au2, and Au3 measured in an mCP film (298 K).

As can be seen from FIG. 1, the Au1, the Au2, and the Au3 exhibit long-lived (46-69 μs) and fine-structured luminescence spectra. The fine-structured luminescence spectra of related Au(C\hat{ }N\hat{ }C)-aryl complexes in the references are attributed to excited states of π-π* features within a primary triple ligand. As can be seen from FIG. 2, both the Au2 and the Au3 present unstructured and broad peak curves, with their luminescence wavelength maxima red-shifted to 520 nm and 544 nm, respectively, different from their fine-structured luminescence spectra presented in degassed toluene. The different luminescence spectra reflect different excited states. The unstructured and broad peak curves are attributed to the formation of the TADF exciplexes, wherein the TAPC host serves as donor molecules and the Au2/Au3 serves as acceptor molecules in the exciplex system. The results show that the Au2 and the Au3 can form a TADF exciplex, which is made into a TADF device, while the Au1 only has phosphorescent properties and fails to be used for the TADF device. As can be seen from FIG. 3, the Au1, the Au2, and the Au3 exhibit luminescence spectra very similar to those measured in degassed toluene, all exhibiting fine structure, and their luminescence is attributed to excited states of π-π* features within the primary triple ligand. This is due to insufficient donor strength of the mCP host and failure to form TADF exciplexes with these gold (III) complexes.

The Au2 and the Au3 were electrochemically characterized and analyzed, with the results as shown in Table 2:

TABLE 2

| Phosphorescent gold | E_{HOMO} | E_{LUMO} | | |
|---|---|---|---|---|
| (III) complex | [eV]^{[2]} | [eV]^{[2]} | Oxidation E_{1/2} [V] | Reduction E_{1/2} [V] |
| Au2 | / | −2.87 | / | −1.54 |
| Au3 | / | −3.02 | / | −1.37 |

[1] Solution of 0.1M nBu₄NPF₆ in DMF at 298K. Values relative to the reference electrode (saturated calomel electrode).
^{[2]}Estimated using E_{HOMO/LUMO} = − [4.8 + (Eₒₙₛₑₜ^{ox/red} vs. Cp₂Fe^{0/+} E_{1/2})] eV.

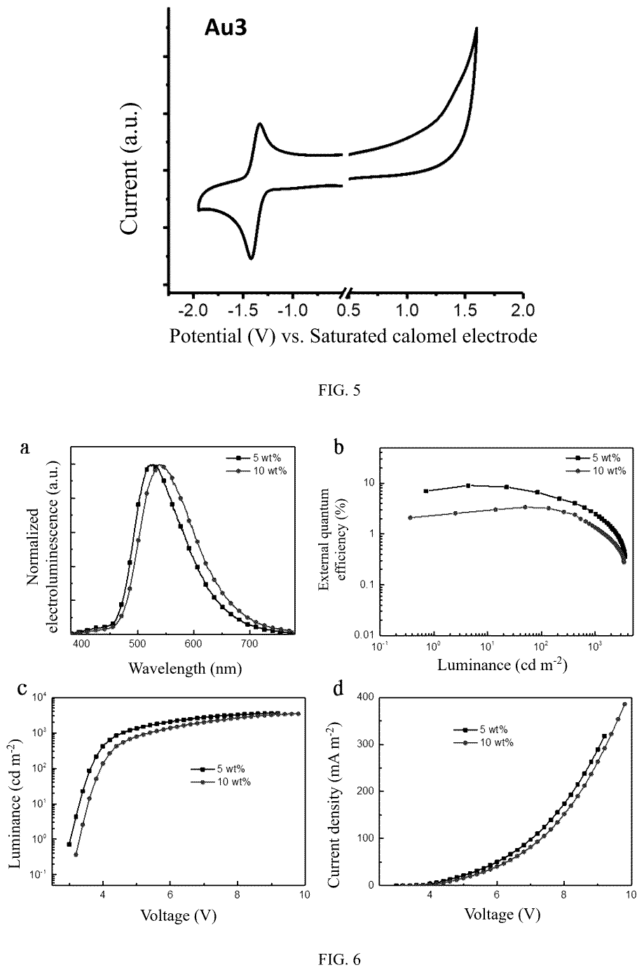

As can be seen from cyclic voltammograms of the Au2 and the Au3 shown in FIG. 4 and FIG. 5, the Au3 has lower LUMO orbital energy than the Au2.

An organic electroluminescent device for the Au2-TAPC exciplex (device structure: ITO/HAT-CN (5 nm)/TAPC (50 nm)/Au2: TAPC (10 nm)/TmPyPb (50 nm)/LiF (1.2 nm)/Al (100 nm)) was characterized with the results as shown in Table 3 and FIG. 6:

TABLE 3

| | | Current | | Power | | External | | |
|---|---|---|---|---|---|---|---|---|
| | | efficiency | | efficiency | | quantum | | |
| Au2 | | [cd A⁻¹] | | [lm W⁻¹] | | efficiency [%] | | Luminescence |
| Doping | Luminance | Peak | 1000 cd | Peak | 1000 cd | Peak | 1000 cd | wavelength |
| concentration | [cd m⁻²] | value | m⁻² | value | m⁻² | value | m⁻² | [nm] |
| 5 wt % | 3600 | 28.5 | 7.8 | 28.0 | 5.3 | 9.0 | 2.6 | 528 |
| 10 wt % | 3430 | 10.7 | 4.2 | 8.8 | 2.5 | 2.5 | 1.3 | 539 |

As can be seen from the data of Table 3 and the data of FIG. 6, the electroluminescence spectrum of this device is similar to the photoluminescence spectrum of the Au2 in the TAPC film (FIG. 2), reflecting that the device also retains the TADF properties. When the voltage is close to 9 V, the device luminance is close to saturation. When the doping concentration of the Au2 is increased to 10 wt %, the luminance, current efficiency, power efficiency, and external quantum efficiency of the device will decrease with less satisfactory effects.

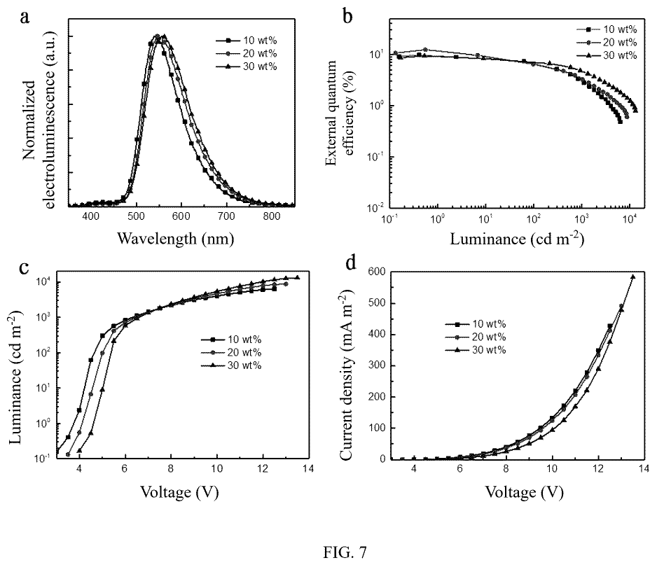

An organic electroluminescent device for the Au3-TAPC exciplex (device structure: ITO/HAT-CN (5 nm)/TAPC (50 nm)/Au3: TAPC: mCP (20 nm)/TmPyPb (50 nm)/LiF (1.2 nm)/Al (100 nm)) was characterized, with the results as shown in Table 4 and FIG. 7:

TABLE 4

| | | Current | | | | External | | |
|---|---|---|---|---|---|---|---|---|
| | | efficiency | | Power efficiency | | quantum | | |
| Au3 | | [cd A⁻¹] | | [lm W⁻¹] | | efficiency [%] | | Luminescence |
| Doping | Luminance | Peak | 1000 cd | Peak | 1000 cd | Peak | 1000 cd | wavelength |
| concentration | [cd m⁻²] | value | m⁻² | value | m⁻² | value | m⁻² | [nm] |
| 10 wt % | 6400 | 29.9 | 8.9 | 29.4 | 4.4 | 9.7 | 3.0 | 540 |
| 20 wt % | 8700 | 36.3 | 9.6 | 28.5 | 4.7 | 12.3 | 3.3 | 550 |
| 30 wt % | 13100 | 26.8 | 13.8 | 19.6 | 6.6 | 9.3 | 4.8 | 556 |

As can be seen from the data of Table 4 and the data of FIG. 7, the electroluminescence spectrum of this device is similar to the photoluminescence spectrum of the Au3 in the TAPC film (FIG. 3), reflecting that the device also retains the TADF properties. The device luminance can increase with the voltage, without saturation. When the doping concentration of the Au3 is increased to 30 wt %, the current efficiency, power efficiency, and external quantum efficiency at 1000 cd m⁻² remain to increase with improved tolerance to variations in the doping concentration of the Au3.

The above description of the disclosed embodiments will enable those having ordinary skills in the art to implement or use the present disclosure. Various modifications to these embodiments will be apparent to those having ordinary skills in the art, and the general principles defined herein can be implemented in other embodiments without departing from the spirit or scope of the present disclosure. Therefore, the present disclosure will not be limited to the embodiments shown herein, but will conform to the widest scope consistent with the principles and novel features disclosed herein.

1. A compound having a structure of formula I: 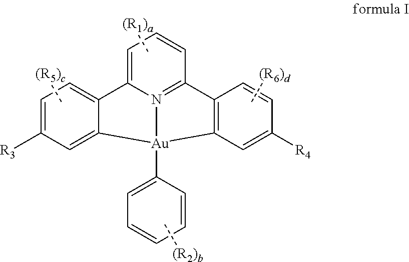
wherein R₁ and R₂ are independently selected from H, halogen, a substituted or unsubstituted C₁-C₆ alkyl, a substituted or unsubstituted C₁-C₆ alkoxy, —O—R₇, a substituted or unsubstituted C₆-C₃₀ aryl, or a substituted or unsubstituted C₄-C₂₀ heteroaryl;
R₇ is independently selected from a substituted or unsubstituted C₁-C₆ alkyl, a substituted or unsubstituted C₆-C₂₀ aryl, or a substituted or unsubstituted C₄-C₂₀ heteroaryl;
a and b are independently selected from any integer of 0 to 3;
a heteroatoms in the heteroaryl is selected from any one or more of N, O, P, or S;
R₃, R₄, R₅, and R₆ are independently selected from H, halogen, nitro, a substituted or unsubstituted C₁-C₆ alkyl, cyano, sulfonyl, acyl, or carboxyl; and
c and d are independently selected from any integer of 0 to 3.

2. The compound of claim 1, wherein R₁ and R₂ are independently selected from H, halogen, a substituted or unsubstituted C₁-C₄ alkyl, —O—R₇, a substituted or unsubstituted C₁-C₄ alkoxy, or a substituted or unsubstituted C₆-C₂₀ aryl.

3. The compound of claim 2, wherein R₃, R₄, R₅, and R₆ are independently selected from H, F, nitro, or trifluoromethyl.

4. The compound of claim 1, wherein a structural formula of the compound is selected from any one of formula 1 to formula 20 below:

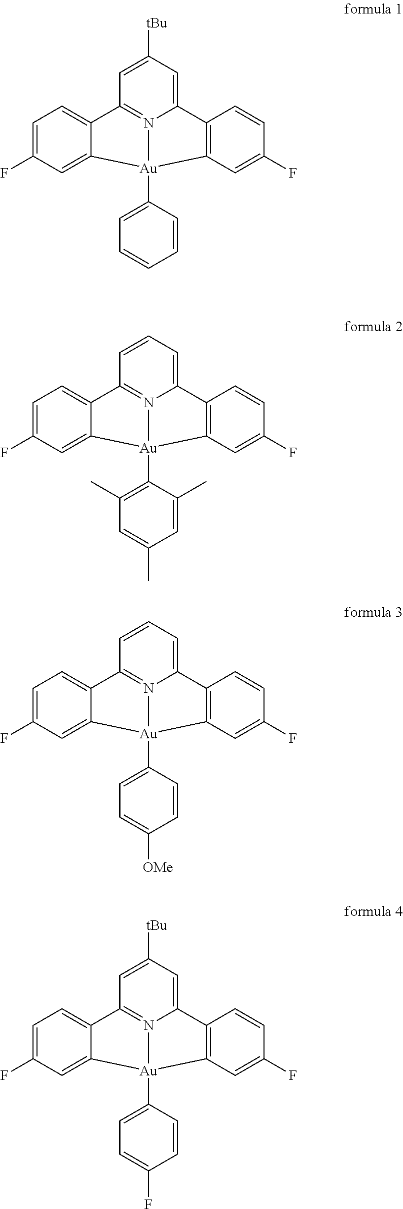

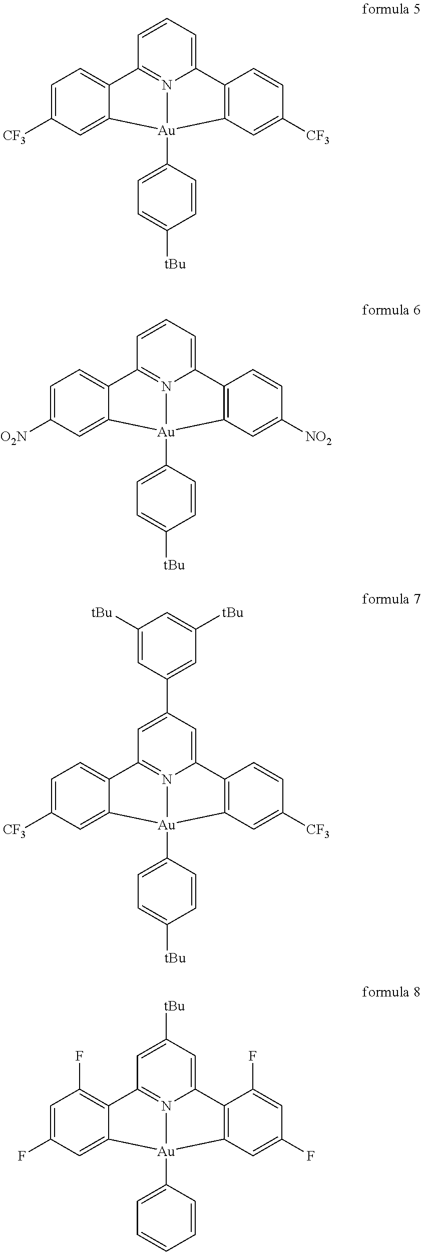

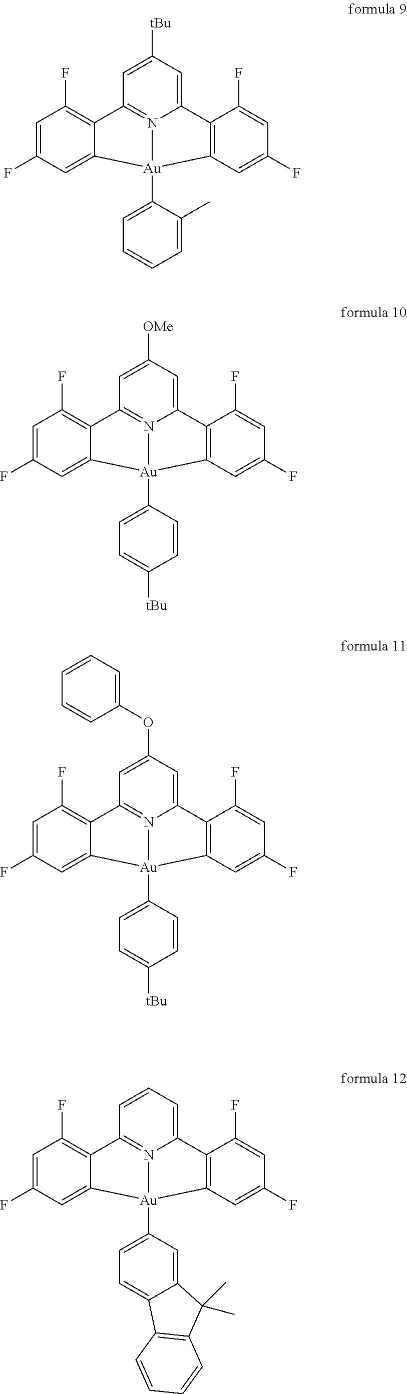

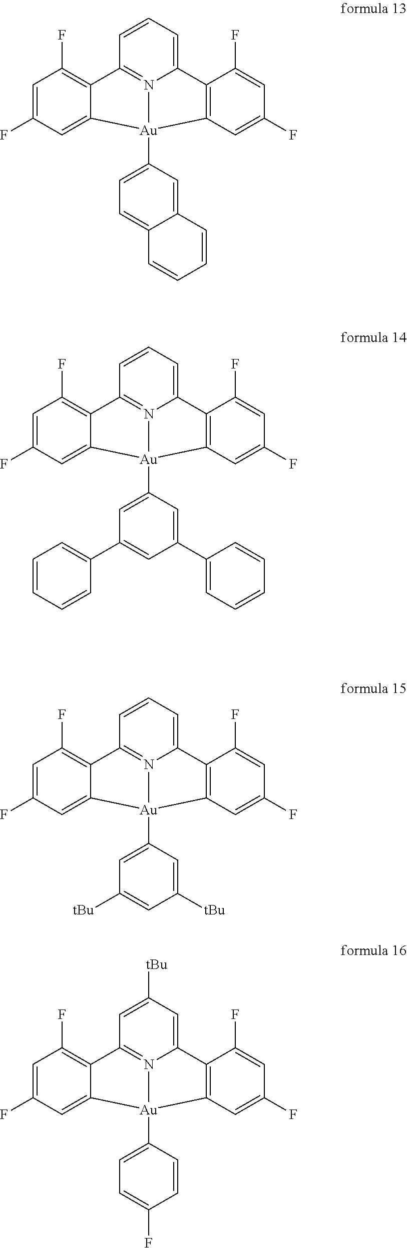

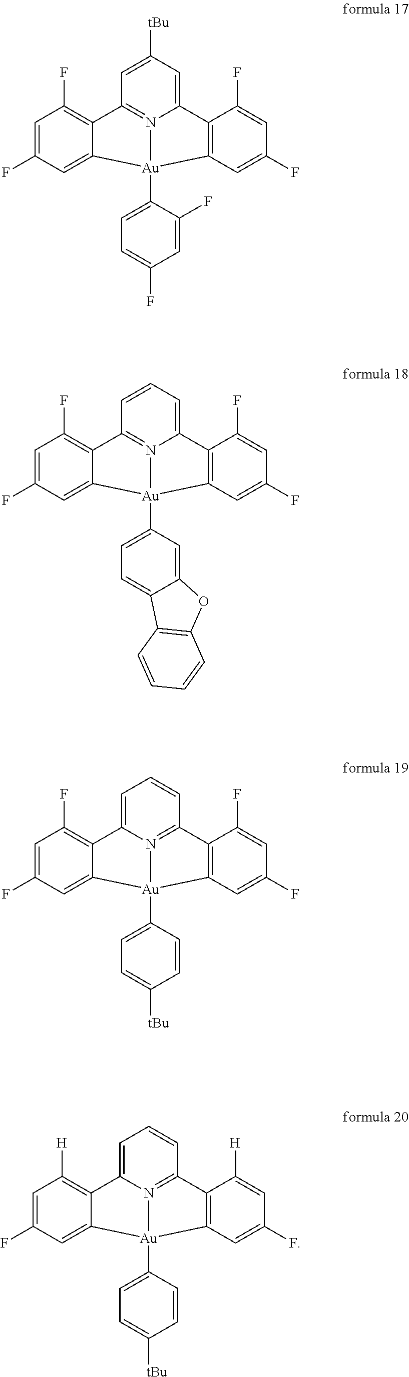

5. A preparation method of the compound of claim 1, comprising the following steps of:
mixing a raw material as shown in formula A, a raw material as shown in formula B, a solvent, a catalyst, and an alkaline substance, and then heating the mixture for reaction to obtain the compound;

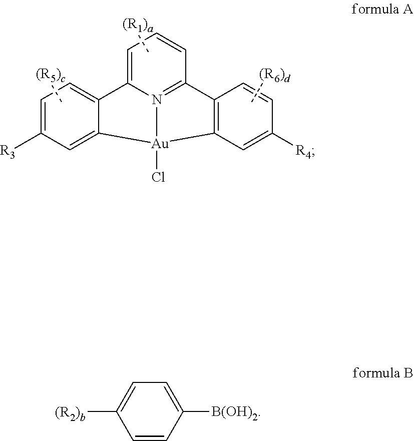

6. The preparation method of claim 5, wherein the solvent comprises toluene;
the catalyst comprises bis(di-tert-butyl (4-dimethylaminophenyl)phosphine)dichloropalladium; and
the alkaline substance comprises potassium carbonate.

7. A TADF exciplex luminophore, comprising a dopant and a host material, wherein:
the dopant is the compound of claim 1.

8. The TADF exciplex luminophore of claim 7, wherein a structural formula of the host material is selected from any one or more of formula (B-1) to formula (B-8) below:

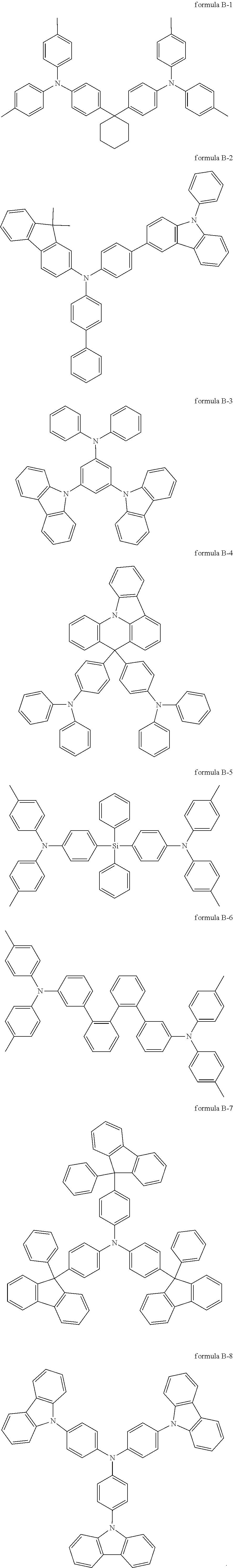

9. (canceled)

10. The TADF exciplex luminophore of claim 7, having a luminescence quantum yield of at least 30% and a luminescence service life of no more than 5 microseconds.

11. An organic electroluminescent device, a light-emitting electrochemical cell, or a chemical sensor, comprising the TADF exciplex luminophore of claim 7.

12. An organic electroluminescent device, comprising an anode, a cathode, and an interlayer arranged between the anode and the cathode,
the interlayer comprises a light-emitting layer; the light-emitting layer comprises the TADF exciplex luminophore of claim 7.

13. The compound of claim 1, wherein b is 2 or 3, two R₂ form, together with a carbon on a benzene ring to which they are attached, a substituted or unsubstituted ring.

14. The compound of claim 1, wherein b is 2 or 3, two R₂ form, together with a carbon on a benzene ring to which they are attached, a substituted or unsubstituted heterocycle.

15. The compound of claim 14, wherein a heteroatom in the heterocycle is selected from any one or more of N, O, P, or S.

16. The compound of claim 1, wherein b is 2 or 3, two R₂ form, together with a carbon on a benzene ring to which they are attached, a substituted or unsubstituted five-membered ring.

17. The compound of claim 1, wherein b is 2 or 3, two R₂ form, together with a carbon on a benzene ring to which they are attached, a substituted or unsubstituted five-membered heterocycle;
a heteroatom in the five-membered heterocycle is selected from any one or more of N, O, P, or S.

18. The compound of claim 1, wherein R₃, R₄, R₅, and R₆ are independently selected from H, halogen, nitro, or a substituted or unsubstituted C₁-C₄ alkyl.

19. A TADF exciplex luminophore, comprising a dopant and a host material, wherein:
the dopant is the compound prepared by using the preparation method of claim 5.

20. The TADF exciplex luminophore of claim 7, wherein a mass ratio of the host material to the dopant is (80-95):(5-20).
